(19) United States
(12) Patent Application Publication
(10) Pub. No.: US 2008/0289766 A1
(43) Pub. Date: Nov. 27, 2008

(54) Hot edge ring apparatus and method for increased etch rate uniformity and reduced polymer buildup

(75) Inventors: David Heemstra, Hutto, TX (US); Rex Silva, Austin, TX (US); Michael Leone, Austin, TX (US); Jim Gernert, Austin, TX (US)

Correspondence Address: DOCKET CLERK, P.O. DRAWER 800889, DALLAS, TX, 75380, US

(73) Assignees: Samsung Austin Semiconductor LP, Austin, TX (US); SAMSUNG ELECTRONICS CO., LTD., SUWON-SI (KR)

(21) Appl. No.: 11/805,100

(22) Filed: May 22, 2007

(51) Int. Cl. H01L 21/30

(52) U.S. Cl. 156/345.51; 438/706

(57) ABSTRACT

An apparatus with an edge ring configured to surround a perimeter of a semiconductor wafer in a semiconductor process, the edge ring having a plurality of protrusions located on an upper surface of the edge ring, the protrusions capable of preventing the semiconductor wafer from moving outside the bounds of a process plane. There is also an apparatus having a semiconductor process chamber and an electrostatic chuck, a semiconductor wafer, and an edge ring. There is also a method including providing a semiconductor process chamber, semiconductor wafer disposed within the semiconductor process chamber, and an edge ring, the edge ring having a plurality of protrusions located on an upper surface of the edge ring, the protrusions capable of preventing the semiconductor wafer from moving outside the bounds of a process plane. The method also includes performing an etch process on the semiconductor wafer.

### TECHNICAL FIELD OF THE INVENTION

The present disclosure relates generally to semiconductor processing and more specifically to plasma semiconductor processes and apparatuses.

### BACKGROUND OF THE INVENTION

Integrated circuit and other semiconductor fabrication processes are well known in the art. The fabrication of an integrated circuit chip typically begins with a thin, polished slice of high-purity, single-crystal semiconductor material substrate (such as silicon or germanium) called a “wafer”, which is them processed in a sequence of physical and chemical processing steps to form various circuit structures on the wafer. During the fabrication process, various types of thin films may be deposited on the wafer using various techniques such as thermal oxidation to produce silicon dioxide films, chemical vapor deposition to produce silicon, silicon dioxide, and silicon nitride films, and sputtering or other techniques to produce other metal films. The semiconductor structure is modified by applying masks, dopants, deposition processes, and etch processes, as known to those of skill in the art.

Vacuum processing chambers are often used for etching and chemical vapor deposition (CVD) of materials on substrates by supplying an etching or deposition gas to the vacuum chamber and application of a radio frequency (RF) field to the gas to energize the gas into a plasma state. However, in plasma processing of wafers, process drift (i.e., the change of process performance over a certain amount of time) can occur, and conventional processes and apparatuses can result in a varying etch rate and a great amount of polymer build up.

There is a need for an improved apparatus and method for increasing etch rate uniformity and reducing polymer build up.

### SUMMARY OF THE INVENTION

The present disclosure an embodiment that includes an apparatus with an edge ring configured to surround a perimeter of a semiconductor wafer in a semiconductor process, the edge ring having a plurality of protrusions located on an upper surface of the edge ring, the protrusions capable of preventing the semiconductor wafer from moving outside the bounds of a process plane.

Another embodiment describes an apparatus having a semiconductor process chamber and an electrostatic chuck disposed within the semiconductor process chamber. The apparatus also includes a semiconductor wafer supported by the electrostatic chuck; and an edge ring, the edge ring having a plurality of protrusions located on an upper surface of the edge ring, the protrusions capable of preventing the semiconductor wafer from moving outside the bounds of a process plane.

Another embodiment includes a method, comprising providing a semiconductor process chamber, providing a semiconductor wafer disposed within the semiconductor process chamber, and providing an edge ring, the edge ring having a plurality of protrusions located on an upper surface of the edge ring, the protrusions capable of preventing the semiconductor wafer from moving outside the bounds of a process plane. The method also includes performing an etch process on the semiconductor wafer.

Other features and advantages of the present disclosure will be apparent to those of ordinary skill in the art upon reference to the following detailed description taken in conjunction with the accompanying drawings.

### BRIEF DESCRIPTION OF THE DRAWINGS

For a better understanding of the disclosure, and to show by way of example how the same may be carried into effect, reference is now made to the detailed description of the disclosure along with the accompanying figures in which corresponding numerals in the different figures refer to corresponding parts and in which:

FIG. 1 illustrates a simplified cross-section view of a plasma processing chamber in accordance with one embodiment of the present disclosure;

FIG. 2 depicts a top view of an edge ring in accordance with disclosed embodiments of the present disclosure;

FIGS. 3A-3D illustrate simplified cross sections of various types of edge rings;

FIGS. 4A and 4B illustrate an edge ring 410 in accordance with disclosed embodiments; and

FIG. 5 depicts a simplified process in accordance with a disclosed embodiment

### DETAILED DESCRIPTION OF THE INVENTION

While the making and using of various embodiments of the present disclosure are discussed in detail below, it should be appreciated that the present disclosure provides many applicable inventive concepts, which can be embodied in a wide variety of specific contexts. Although described in relation to such apparatus and methods, the teachings and embodiments of the present disclosure may be beneficially implemented with a variety of manufacturing and applications. The specific embodiments discussed herein are, therefore, merely demonstrative of specific ways to make and use the disclosure, and do not limit the scope of the disclosure.

In the processing of a substrate, e.g., a semiconductor wafer or a glass panel such as one used in flat panel display manufacturing, plasma is often employed.

As part of the processing of a semiconductor wafer, for example, the wafer is divided into a plurality of dies, or rectangular areas, each of which will become an integrated circuit. The wafer is processed in a series of steps in which materials are removed and deposited, e.g., by etching and deposition, in order to form electrical components thereon.

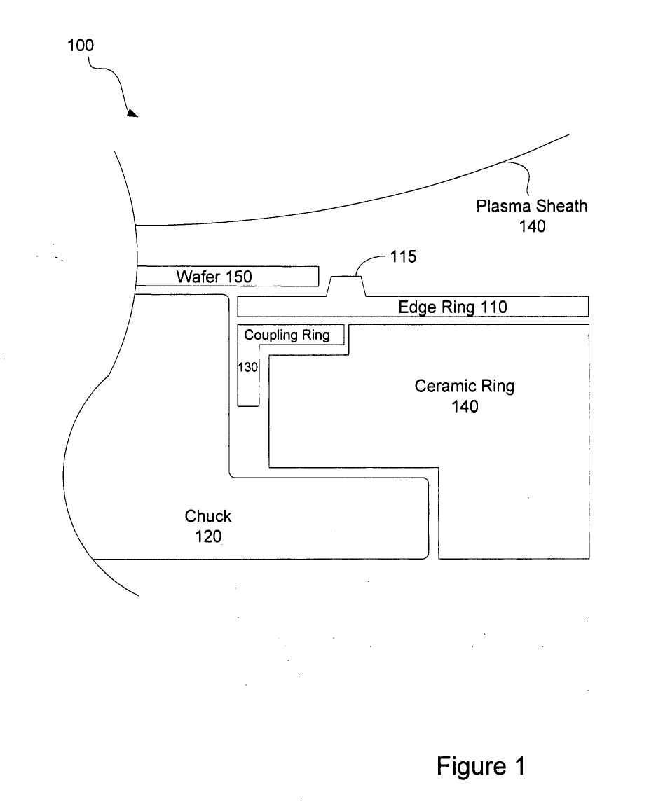

FIG. 1 illustrates a simplified cross-section view of a plasma processing chamber 100 in accordance with one embodiment of the present disclosure. In an exemplary plasma etching process, the wafer 150 is coated with a thin film of hardened emulsion (i.e., such as a photoresist mask) prior to etching. Areas of the hardened emulsion are then selectively removed, causing parts of the underlying layer to become exposed. The wafer 150 is then placed in a plasma processing chamber 100 on a negatively charged electrode, called an electrostatic chuck 120. Appropriate etchant source gases are then flowed into the chamber and struck to form a plasma to etch exposed areas of the underlying layer(s).

In an exemplary plasma deposition process, plasma is also employed to facilitate and/or improve deposition from the source deposition materials.

In many plasma processing chambers 100, an edge ring 110 is often employed. Wafer 150 sits on a chuck 120 that supports the wafer 150 in the plasma processing chamber 100. Chuck 120 acts as a workpiece holder and may be electrically energized by an RF power source to facilitate etching and deposition, as known to those of skill in the art.

A coupling ring 130 is shown disposed between chuck 120 and a ceramic ring 140. One of the functions of coupling ring 130 includes providing a current path from chuck 120 to edge ring 110. Edge ring 110 performs many functions, including positioning wafer 150 on chuck 120 and shielding the underlying components not protected by the wafer itself from being damaged by the ions of the plasma. Projection 115 is described below.

One function of edge ring 110 relates to its effect on process uniformity across the substrate. It is well known that the equipotential lines of the plasma sheath 140 curve upward sharply past the edge of the chuck 120. Without an edge ring 110, the wafer edge electrically defines the outer edge of the chuck, and the equipotential lines would curve upward sharply in the vicinity of the wafer edge. As such, areas of the wafer around the wafer edge would experience a different plasma environment from the plasma environment that exists at the center of substrate, thereby contributing to poor process uniformity across the substrate surface.

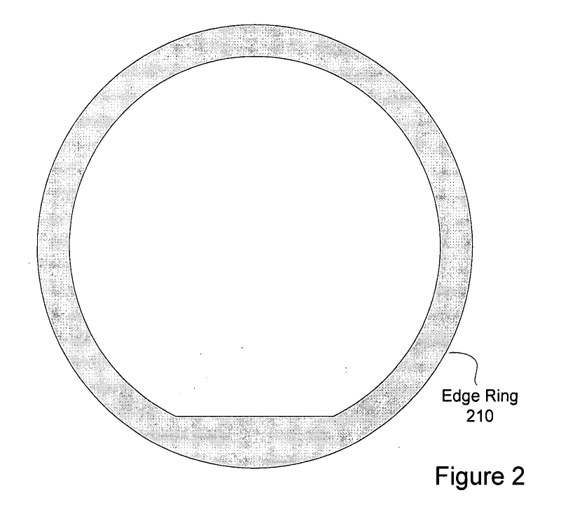

FIG. 2 depicts a top view of an edge ring 210 in accordance with disclosed embodiments. Edge ring 210 surrounds a wafer (not shown) such as wafer 150 of FIG. 1.

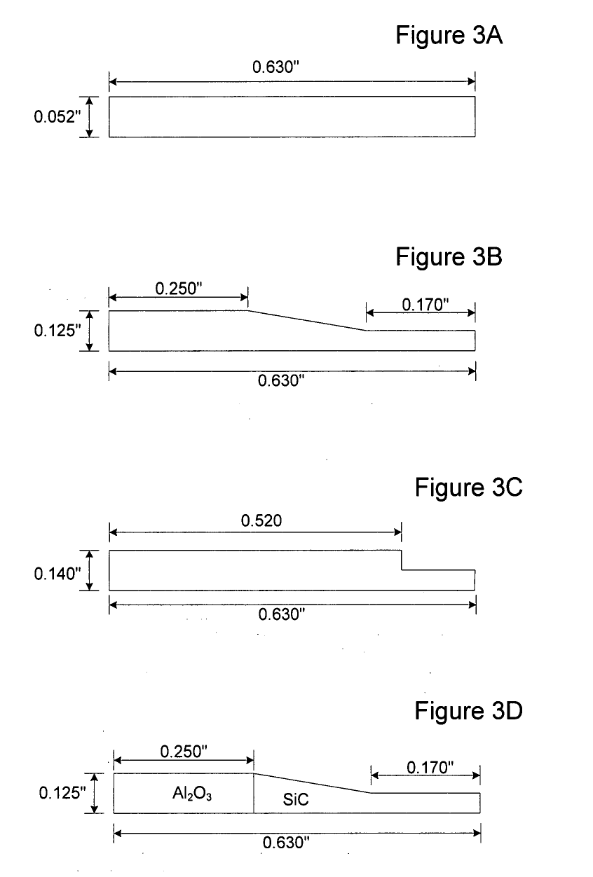

FIGS. 3A-D illustrate simplified cross sections of various types of edge rings. Exemplary dimensions are shown, but the disclosed edge rings may be of other dimensions. Drawings are not to scale.

Many designs and materials have been tested to reduce polymer generation for the Pad Etch process. Several designs can be made out of Aluminum Aluminum Oxide (Al₂O₃), and a 2-piece design shown in FIG. 3D can be made from both Al₂O₃ and Silicon Carbide (SiC).

FIG. 3A illustrates a cross section of a flat edge ring. This edge ring has a uniform thickness designed to reduce polymer buildup. A conventional flat edge ring can result in broken wafers due to the wafer sliding upon being de-chucked from the electrostatic chuck.

FIG. 3B illustrates a cross section of a beveled edge ring design. A beveled edge ring design can be used to prevent wafers from breaking, as was the case of the flat edge ring. The beveled edge ring design prevents wafers from sliding. In some cases, however, large particles are visible at 1× around the edge of the wafer due to the high power of the process and the beveled edge design.

FIG. 3C illustrates a cross section of a standard edge ring design. The standard edge ring has a 90-degree edge that prevents the wafer from sliding as well as prevents particles from sputtering off onto the edge of the wafer.

FIG. 3D illustrates a cross section of a 2-piece design that can be used to reduce polymer generation in the pad etch process. A standard edge ring (as described above) can be made from SiC. This gave undesirable results due to the reduced etch rate at the edge of the wafer. Test results showed that the SiC ring could only be used a single time, with a very high replacement cost. The two-piece design, in one embodiment, uses a beveled SiC interior ring combined with an Al₂O₃ flat outer ring.

Various embodiments disclosed herein include a hardware modification that reduces the amount of byproduct that builds up on the edge ring 110. In one disclosed embodiment, the edge ring 110 is Al₂O₃ that isolates the wafer 150 from the ceramic ring 140 and other underlying portions of chamber 100. Of course, those of skill in the art will recognize that other dielectric materials, such as SiC and other known materials, can be used for the edge ring 110. The hardware modification includes a plurality of surface projections that lies beneath the plane of the wafer and includes several projections that prevent wafer 150 from sliding outside the bounds of the process plane. The disclosed projections reduce excessive wafer movement, and also reduce the buildup of highly stable plasma process byproducts. This modification increases the uniformity of the etch rate by lowering the plane of the dielectric material.

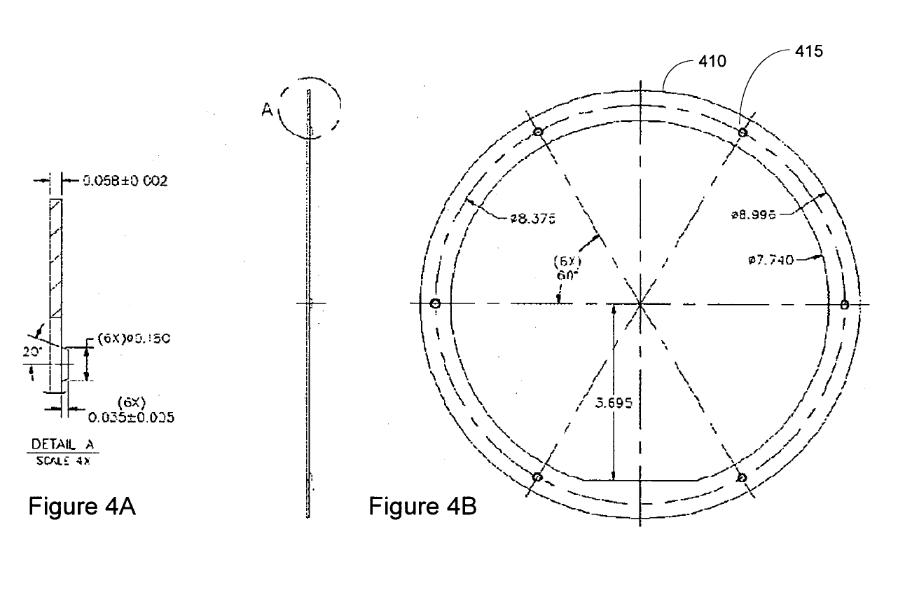

FIGS. 4A and 4B illustrate an edge ring 410 in accordance with disclosed embodiments. Here, a plurality of projections 415 are located at various points around the edge ring 410, and these projections serve to maintain the position of the wafer while achieving a more uniform etch rate. In this particular figure, six projections are dispersed at 60-degree intervals around the edge ring, at approximately the center of the ring. Of course, more or fewer projections could be used. In this example, the main body of the edge ring is approximately 0.052″ thick, each projection has a circular profile approximately 0.150″ in diameter, and each projection has a height above the surface of the edge ring of approximately 0.035 inches, although those of skill in the art will recognize that these dimensions and the profile shape of the projections can be altered to fit particular implementations. For example, the projections could also be oval, square, rectangular, or otherwise, or could be shaped to accommodate the edge of the wafer.

Preferably, but not necessarily, the height of the projections do not extend past the surface level of the wafer itself. Projection 115 of edge ring 110 is shown in cross-section in FIG. 1, illustrating the height relative to the wafer 150 (although these figures are not to scale). Note that the sides of projection 115 are beveled. An angle of 20 degrees from normal is particularly advantageous, although any angle can be used according to particular implementations.

The disclosed edge ring increases etch rate uniformity and reduces polymer build up as compared to a standard edge ring.

The disclosed edge ring can also be modified to remove a thin layer, such as 0.005″ to 0.008″, around the inside diameter to allow the use of Y₂O₃ coating. The material removed from the inside edge is enough to compensate for the additional coating thickness.

The disclosed hot edge ring reduces the amount of polymer (such as Aluminum Fluoride) buildup within the process chamber. The dissociation of CₓF_{y}, SFₓ or CHₓF_{y} in the presence of a Radio Frequency (RF) source will form a plasma that can attack aluminum from chamber parts (typically either Al or Al₂0₃) to produce AlF polymer. This polymer is highly stable and remains in the process chamber unless the chamber is cleaned or undergoes some aggressive plasma clean with corrosive gases (HBr, Cl₂). As is the case in most plasma process chambers, an inert gas (Helium, Argon, etc.) is flown at a fixed pressure between the wafer and the surface of the electrostatic chuck (ESC) to cool the wafer and prevent damage to the wafer. This is commonly called Back Side Helium (BS He) flow. Common failures for this process setup are high cooling flows required to maintain pressure due to polymer flaking and falling onto the ESC. Wafer damage can occur and result in scrapped wafers if flows are too high. Typically photoresist will burn due to excessive temperatures as a result of inadequate cooling. Polymer peeling from the edge of a standard edge ring is a common failure mechanism.

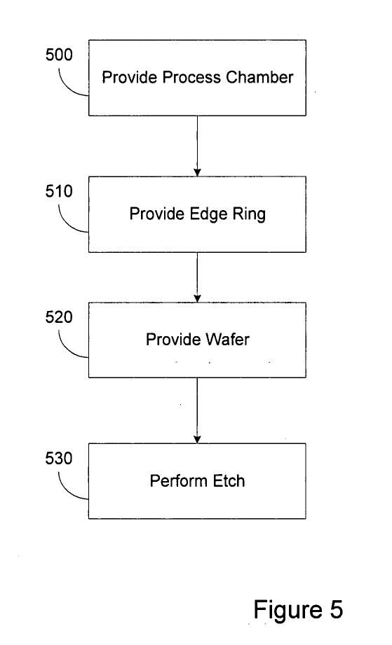

FIG. 5 depicts a simplified process in accordance with a disclosed embodiment. First, provide a process chamber 100 (step 500). Next, provide an edge ring 110 having a plurality of projections 115 (step 510). Next, provide a wafer substrate 150 (step 520). Next, perform an etch process (step 530) on the wafer 150.

The embodiments and examples set forth herein are presented to best explain the present disclosure and its practical application and to thereby enable those skilled in the art to make and utilize the disclosed embodiments.

However, those skilled in the art will recognize that the foregoing description and examples have been presented for the purpose of illustration and example only. The description as set forth is not intended to be exhaustive or to limit the disclosed embodiments to the precise form disclosed. Many modifications and variations are possible in light of the above teaching without departing from the spirit and scope of the following claims.

What is claimed is:

1. An apparatus, comprising:
an edge ring configured to surround a perimeter of a semiconductor wafer in a semiconductor process, the edge ring having a plurality of protrusions located on an upper surface of the edge ring, the protrusions capable of preventing the semiconductor wafer from moving outside the bounds of a process plane.

2. The apparatus of claim 1, wherein the edge ring includes six equally spaced protrusions.

3. The apparatus of claim 1, wherein the protrusions do not extend above an upper surface of the semiconductor wafer.

4. The apparatus of claim 1, wherein the protrusions have a height above the upper surface of the edge ring of approximately 0.035 inches.

5. The apparatus of claim 1, wherein the protrusions have a diameter of approximately 0.150 inches.

6. The apparatus of claim 1, wherein the upper surface of the edge ring is substantially planar in portions other than the protrusions.

7. The apparatus of claim 1, wherein the edge ring increases etch rate uniformity as compared to a standard edge ring.

8. The apparatus of claim 1, wherein the edge ring is made of Al₂0₃.

9. The apparatus of claim 1, wherein the edge ring reduces polymer build up as compared to a standard edge ring.

10. An apparatus, comprising:
a semiconductor process chamber;
an electrostatic chuck disposed within the semiconductor process chamber;
a semiconductor wafer supported by the electrostatic chuck; and
an edge ring, the edge ring having a plurality of protrusions located on an upper surface of the edge ring, the protrusions capable of preventing the semiconductor wafer from moving outside the bounds of a process plane.

11. The apparatus of claim 10, wherein the edge ring includes six equally spaced protrusions.

12. The apparatus of claim 10, wherein the protrusions do not extend above an upper surface of the semiconductor wafer.

13. The apparatus of claim 10, wherein the protrusions have a height above the upper surface of the edge ring of approximately 0.035 inches.

14. The apparatus of claim 10, wherein the protrusions have a diameter of approximately 0.150 inches.

15. The apparatus of claim 10, wherein the upper surface of the edge ring is substantially planar in portions other than the protrusions.

16. The apparatus of claim 10, wherein the edge ring increases etch rate uniformity as compared to a standard edge ring.

17. The apparatus of claim 10, wherein the edge ring is made of Al₂0₃.

18. The apparatus of claim 10, wherein the edge ring reduces polymer build up as compared to a standard edge ring.

19. A method, comprising:
providing a semiconductor process chamber;
providing a semiconductor wafer disposed within the semiconductor process chamber;
providing an edge ring, the edge ring having a plurality of protrusions located on an upper surface of the edge ring, the protrusions capable of preventing the semiconductor wafer from moving outside the bounds of a process plane; and
performing an etch process on the semiconductor wafer.

20. The method of claim 19, wherein the edge ring includes six equally spaced protrusions that do not extend above an upper surface of the semiconductor wafer.
